(19) United States
(12) Patent Application Publication
(10) Pub. No.: US 2005/0102113 A1
(43) Pub. Date: May 12, 2005

(54) System and method for detecting motion of an electric actuator

(75) Inventors: Herman Miracle, Lexington, KY (US); Ivica L. Simic, Lexington, KY (US)

Correspondence Address: ARENT FOX KINTNER PLOTKIN & KAHN, 1050 CONNECTICUT AVENUE, N.W., SUITE 400, WASHINGTON, DC, 20036, US

(73) Assignee: Kaba-Mas Corporation

(21) Appl. No.: 10/969,936

(22) Filed: Oct. 22, 2004

Related U.S. Application Data
(60) Provisional application No. 60/513,538, filed on Oct. 24, 2003.

(51) Int. Cl. G01R 19/00

(52) U.S. Cl. 702/64

(57) ABSTRACT

A system, device, and method of detecting motion of an electric actuator are disclosed. The supply voltage is measured. The measured supply voltage is compared to a previously measured voltage or a predetermined voltage. When the measured supply voltage is the larger voltage, then the electric actuator is considered or determined to have moved properly.

### BACKGROUND OF THE INVENTION

1. Field of the Invention

This invention relates to detecting motion of electric actuators, and specifically to a status monitoring system, which is capable of identifying the status of operation of the lock to a user.

2. Description of Related Art

Electric actuators have many applications, including electronic/electric locks, electric valves, and robotics. In these applications, external sensors are used to determine movement of the actuator. For example, electric valves often use a moveable magnet and reed switches to track the movement of the valve stem. Robotic actuators can use potentiometers to measure actuator movement. These sensors add to the cost of the device and add an additional failure point in a control system.

In some electric or electronic locks, bolt pressure slides the bolt into the lock case. To prevent the lock from being forced open a gate or other blocking device engages the lock case (compare FIG. 7 to FIG. 8). When the gate or other device is in the blocking position, the electric actuator (FIGS. 7-10 use a solenoid plunger for illustrative purposes) is typically unable to fully or properly move.

While bolt pressure can result from a thief trying to force the lock open, often bolt pressure is caused by an error of an authorized operator. Current electric or electronic locks, however, do not provide the user any indication that bolt pressure prevented proper lock operation. With proper indication of this condition the operator would know that the bolt pressure has to be removed in order to open the lock.

### SUMMARY OF THE INVENTION

The system disclosed herein provides a system for detecting the motion of electric actuators. A voltage detector measures the supply voltage of the electric actuator. A voltage comparator compares the measured voltage to a previous voltage. An actuator motion detector detects actuator motion when the output of the voltage comparator indicates that the measured voltage is larger than the previous voltage.

The method disclosed herein provides a method for detecting the motion of electric actuators. The supply voltage of the electric actuator is measured. The measured supply voltage is compared to a previous voltage. Motion of the electric actuator is detected when the measured voltage is larger than the previous voltage.

### BRIEF DESCRIPTION OF THE DRAWINGS

FIG. 1 illustrates an exemplary plot of solenoid supply voltage during the pick pulse when the solenoid plunger did not move;

FIG. 2 illustrates an exemplary plot of solenoid supply voltage during the pick pulse when the solenoid plunger operated;

FIG. 3 illustrates a basic process that may be used to detect movement of an electric actuator;

FIG. 4 illustrates a second embodiment of the invention that has improved reliability over the process illustrated in FIG. 3;

FIG. 5 illustrates a third embodiment of the invention that has improved reliability over the process illustrated in FIG. 3;

FIG. 6 illustrates a fourth embodiment of the invention that uses an alternate process to that illustrated in FIG. 3;

FIG. 7 illustrates an example of the bolt position when pressure is present;

FIG. 8 illustrates an example of the bolt position when no pressure is present;

FIG. 9 illustrates a fifth embodiment of the invention that provides an exemplary process that may be used in a lock to detect a change in the slope of the solenoid supply voltage;

FIG. 10 provides an exemplary circuit that may be used to detect the solenoid supply voltage; and

FIG. 11 is a block diagram for an electric actuator motion detector.

### DETAILED DESCRIPTION OF THE PRESENT INVENTION

When a voltage is applied to an electric actuator, the EMF is related to the motion of the actuator or a part thereof. This EMF may be detected and/or monitored by monitoring the supply voltage.

Electric actuators are devices that move or cause motion when an electric current is applied to or removed from the actuator. Examples of these actuators include, but are not limited to: solenoids, motors, etc.

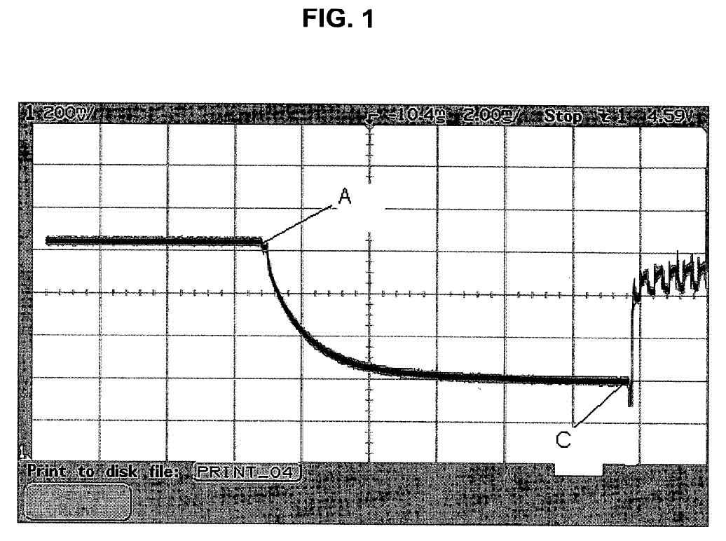

The currently preferred embodiment uses a solenoid as the electric actuator. Accordingly, FIG. 1 illustrates an exemplary plot of solenoid supply voltage over time when the solenoid plunger fails to move while a voltage is applied to the solenoid. In FIG. 1, a voltage is applied to the solenoid between point A (beginning of the pick pulse) and point C (end of the pick pulse). The continuously decreasing voltage during the pick pulse indicates that little or no motion by the solenoid plunger occurred.

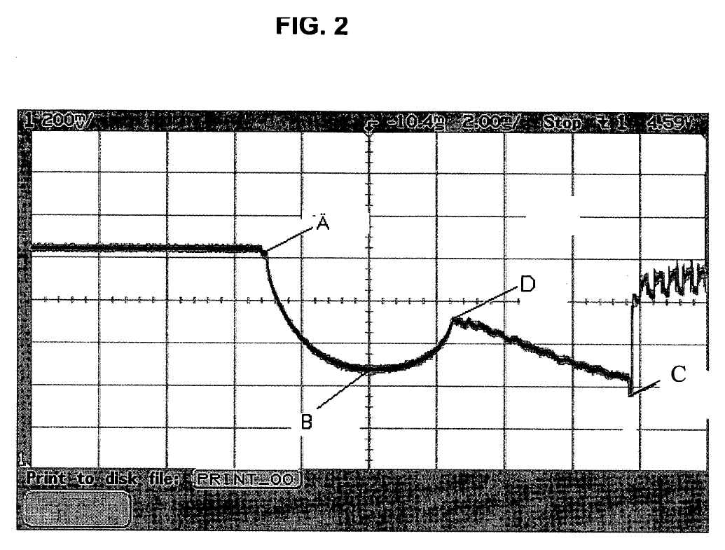

In contrast, FIG. 2 illustrates an exemplary plot of solenoid supply voltage over time when the solenoid plunger moves properly while a voltage is applied to the solenoid. In FIG. 2, a voltage is applied to the solenoid from point A (beginning of the pick pulse) to point C (end of the pick pulse). In FIG. 2, the voltage initially decreases after point A. This decrease is similar to the decrease shown in FIG. 1. In contrast to FIG. 1, however, the voltage in FIG. 2 increases for a period of time beginning at point B and ending at point D. This voltage increase during the pick pulse indicates that the solenoid plunger moved.

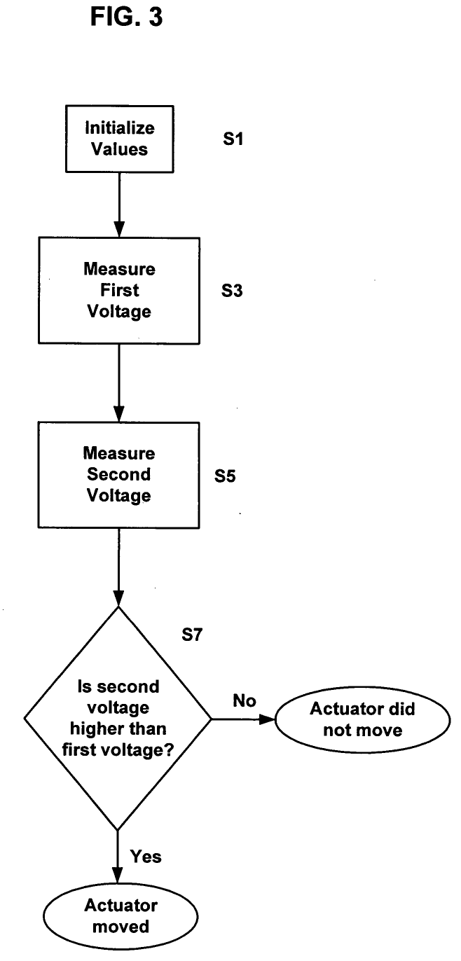

FIG. 3 illustrates a basic process that may be used to detect the movement of an electric actuator. Typically, the process would operate on a microcontroller or microprocessor. In some embodiments, the process could operate in an ASIC or other hardware device.

The process is initialized, if necessary, in step S1. A first or initial actuator supply voltage is measured in step S3. Thereafter, a second actuator supply voltage is measured in step S5. In step S7, the second voltage is compared with the first voltage. When the second voltage is higher than the first voltage, the process may indicate that the actuator has moved. In contrast, if the second voltage is not higher than the first voltage, then this would be an indication that the actuator did not move.

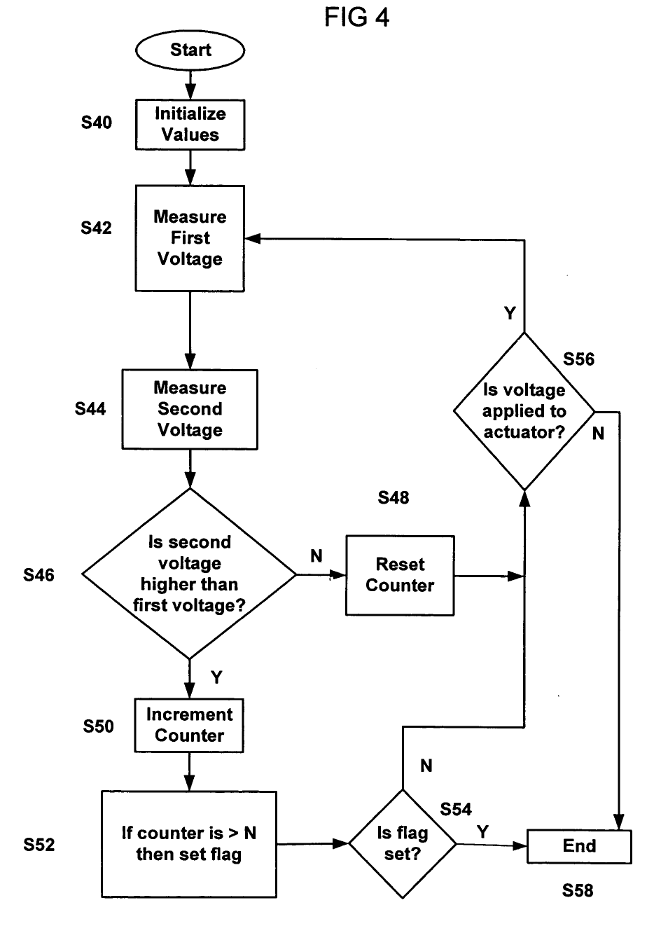

FIG. 4 illustrates a second embodiment of the invention that has improved reliability over the process illustrated in FIG. 3. Similar to the process illustrated in FIG. 3, the process illustrated in FIG. 4 operates on a microcontroller or microprocessor. In other embodiments, the process could operate in an ASIC or other hardware device.

The process illustrated in FIG. 4 is initialized, if necessary, in step S40. In step S42, the first actuator supply voltage is measured. Thereafter, in step S44, a second actuator supply voltage is measured. In step S46, the first and second actuator supply voltages are compared. When the second voltage is not higher than the first voltage, a counter is reset in step S48. When the second voltage is higher than the first voltage, the counter is incremented in step S50. Thereafter, the process shown in FIG. 4 checks to see if the counter is larger than a predetermined number N. When the counter is larger than, or equal to, the predetermined number, then a flag is set. When the predetermined number N is 1, the process of FIG. 4 is essentially the same as that illustrated in FIG. 3. When the predetermined number N is 2 or larger, then the process illustrated in FIG. 4 will have improved reliability over that illustrated in FIG. 3 since circuit noise or transient conditions could not cause an improper indication that the actuator moved. If the predetermined number N is set too high, then it is possible that even thought the actuator moved, the process illustrated in FIG. 4 would not detect this movement.

In step S54, the process checks to see if the flag was set. When the flag is set, the process ends at step S58 and would indicate that the actuator moved. When the flag is not set in step S54, or the counter was reset in step S48, then the process checks to see if voltage continues to be applied to the actuator in step S56. If voltage continues to be applied, then the process returns to step S42. If voltage is no longer applied, then the process would end at step S58 with an indication that the actuator had not moved.

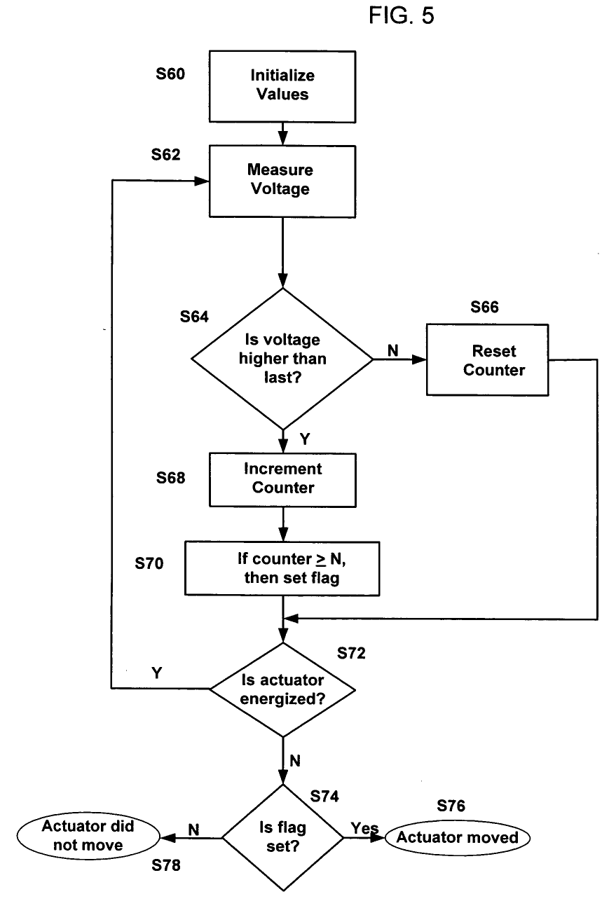

FIG. 5 illustrates a third embodiment of the invention that also has improved reliability over the process illustrated in FIG. 3. This process may also be used to determine if the electronic actuator properly moved and typically operates on a microcontroller or microprocessor. In some embodiments, the process could operate in an ASIC or other hardware device.

The process illustrated in FIG. 5 is initialized, if necessary, in step S60. In step S62, the supply voltage to the actuator is measured. In step S64, the measured voltage is compared with a previously or last measured voltage. When the measured voltage is higher than the previous or last voltage, the process moves to step S68. When the voltage is not higher than the previous or last voltage, then a counter is reset in step S66. In step S68 a counter is incremented. Thereafter, if the counter is greater than, or equal to, a predetermined number N, then a flag is set in step S70. Thereafter, the process flow in FIG. 5 moves from either step S66 or step S70 to step S72 which determines whether the actuator is still energized. When the actuator is still energized, the process returns to step S62. When the actuator is not energized, then the process continues to step S74 which checks to see if a flag has been set. If the flag is set, this indicates that the actuator moved in step S76, and if a flag is not set, this indicates that the actuator did not move in step S78.

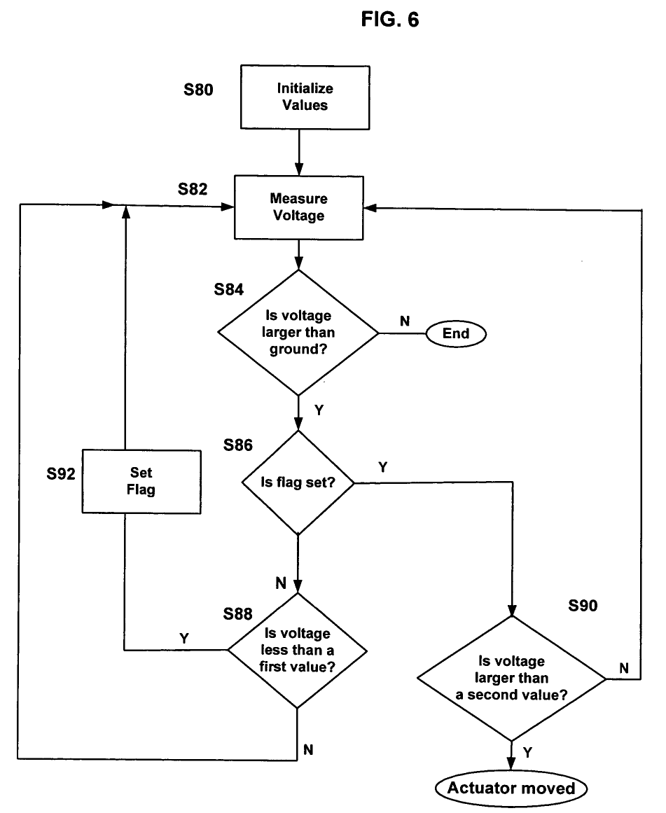

FIG. 6 illustrates a fourth embodiment of the invention that uses an alternate process to that illustrated in FIG. 3. This process may also be used to determine if an electronic actuator properly moved when a voltage was applied to the actuator. Typically, the process operates on a microcontroller or microprocessor. In some embodiments, the process could operate in an ASIC or other hardware device.

The process is initialized, if necessary, in step S80. The supply voltage to the electric actuator is measured in step S82. Thereafter, this voltage is compared to ground in step S84. If the measured voltage is not larger than ground, then the process ends.

When the measured voltage is larger than ground, then the process checks to see if a flag is set in step S86. When the flag is set, the process flow continues to step S90 which checks to see if the measured voltage is larger than a second value. When the voltage is not larger than a second value, the process flow would return to step S82. If the voltage is larger than a second value, then the process would end with an indication that the actuator moved.

If the flag in step S86 is not set, then the process flow continues to step S88 where the process checks to see if the voltage is less than a first value. If the voltage is not less than a first value, then the process flow returns to step S82.

When the measured voltage is less than a first value, then a flag is set in step S92. After setting the flag, the process returns to step S82.

In some embodiments, the first and second values may be the same. In the typical embodiment, however, the first value is lower than the second value. The process illustrated in FIG. 6 takes advantage of the shape of the supply voltage curve illustrated in FIG. 2 which illustrates that the voltage initially decreases after point A but then increases for the period of time beginning at point B. Thus, the first and second values of FIG. 6 must be between the voltage of point B and the voltage of point D. The actual voltage selected for the first and second values would be dependent upon the particular actuator being used.

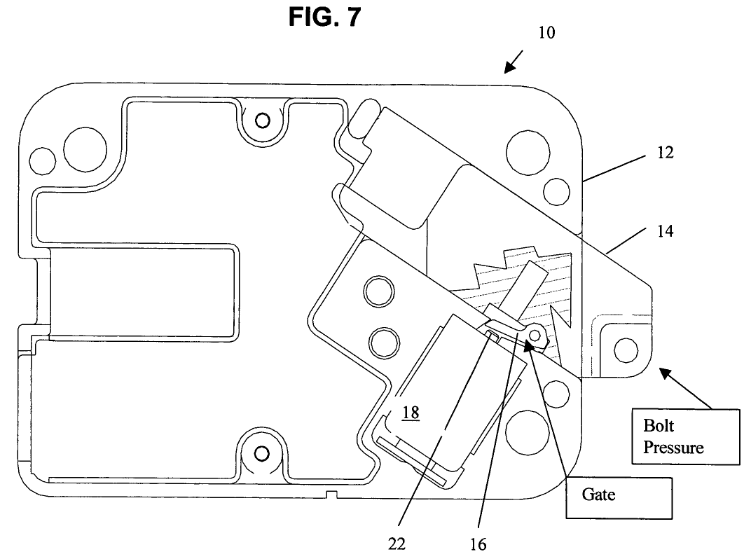

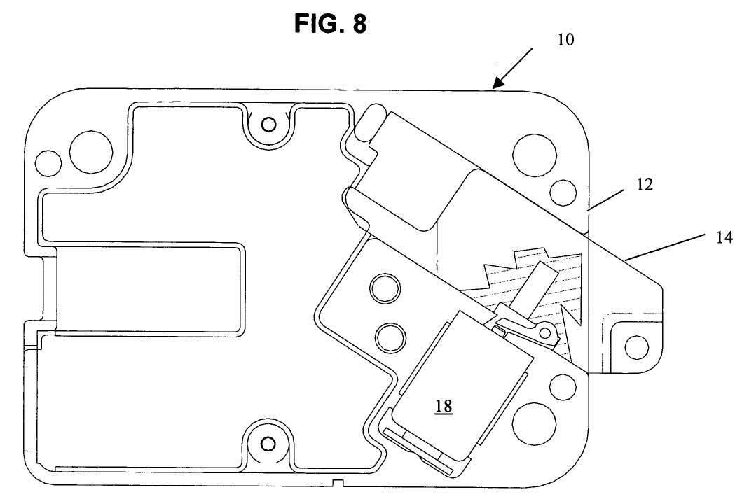

FIGS. 7 and 8 provide one example of the bolt works for an electronic lock. FIG. 8 illustrates exemplary positions of the components of lock 10 when no pressure has been applied to the bolt. In contrast, FIG. 7 illustrates exemplary positions of the components of lock 10 when pressure has been applied to the bolt.

In FIGS. 7 and 8, electronic lock 10 has a case 12 that carries and/or supports bolt 14. In the lock 10 shown, the bolt 14 caries a gate 16 to prevent the lock 10 from being forced open. Other locks use one or more blocking devices to prevent the lock from being forced open.

In lock 10, bolt pressure slides the bolt 14 into the case 12 (compare FIG. 7 to FIG. 8). With the solenoid de-energized, the gate 16 engages the lock case 12. When the gate 16 is in the blocking position (shown in FIG. 7), the solenoid plunger 22 of solenoid 18 is not able to fully or properly move when voltage is applied during a pick pulse.

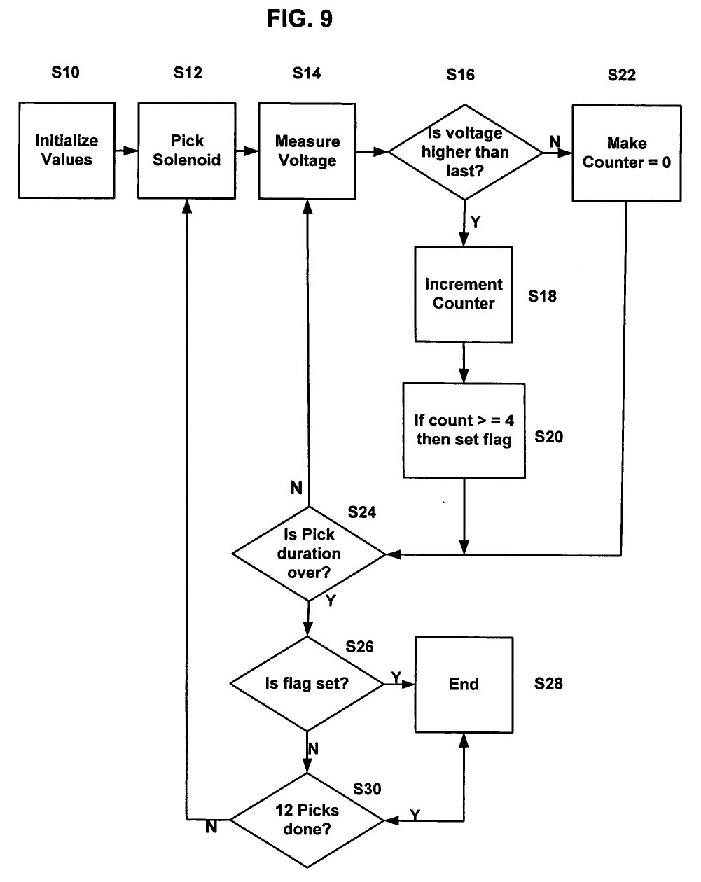

FIG. 9 illustrates the currently preferred process that may be used to determine if the solenoid plunger 22 properly moved when the pick pulse was applied to the solenoid 18. Typically, the process would operate on a microcontroller or microprocessor. In some embodiments, the process could operate in hardware such as an ASIC.

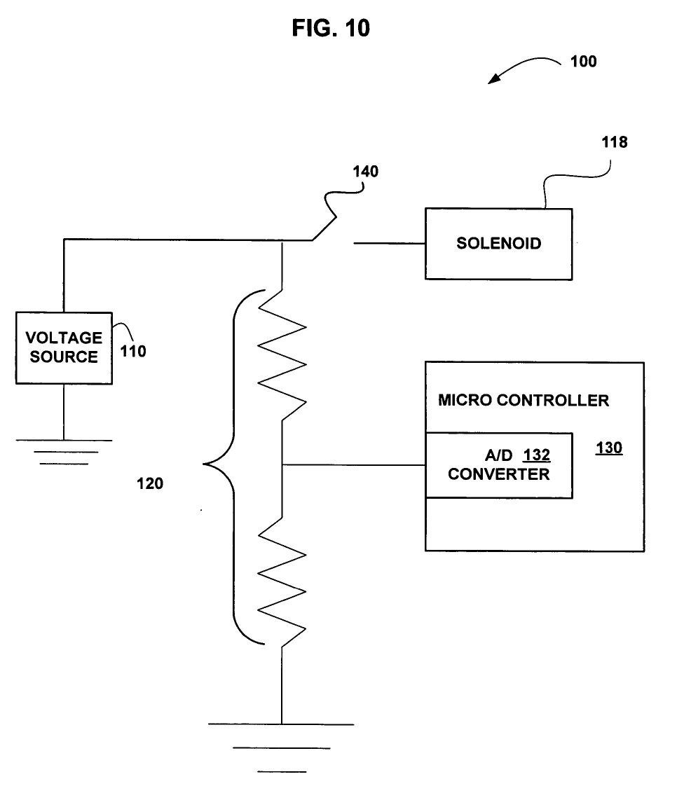

The process is initialized, if necessary, in step S10. After an authorized combination is entered into the electronic lock, a pick pulse is applied to solenoid 18 in step S12. The solenoid supply voltage is measured in step S14. FIG. 10 (discussed below) illustrates an exemplary circuit that may be used to measure the solenoid supply voltage.

In step S16 the current and previous solenoid supply voltages are compared. If the current voltage is the same as or lower than the previous voltage, then a counter is set to zero in step S22. Alternatively the counter could be reset or set to a predetermined number.

When the current voltage is larger than the previous voltage, then a counter is incremented in step S18. Thereafter, the counter is compared to a predetermined number in step S20. In the embodiment illustrated in step S20, the predetermined number is four indicating that the voltage has increased for four consecutive cycles. This value was selected based on the time that the solenoid supply voltage rises after point B (i.e. the time between points B and D) for the particular solenoid used in the lock and the clock speed of the microcontroller, microprocessor, or other device performing the process to detect the movement of the plunger 22 of solenoid 18.

Other values of the predetermined number could be used. The value of the predetermined number or the number of voltage comparisons should be such that a particular inflection behind point B (FIG. 2) can be detected. A number of consecutively increasing values indicates the presence of this inflection. If this inflection is seen, it is inferred that the solenoid plunger has properly moved.

If the predetermined number or the number of voltage comparisons is too small there is the risk that the inflection detected was caused by noise in the circuit and not proper motion of the solenoid plunger 22. If the predetermined number or the number of voltage comparisons is too large there is the risk that the inflection would not be detected since the voltage decreases again after point D.

In step S20 if the counter is larger than the predetermined value or the predetermined number of voltage comparisons has been made, then a flag or bit is set to indicate that the solenoid plunger 22 properly moved. In other embodiments, other processes or tools could be used to store or convey this information.

After either step S20 or S22 the process checks to see if the pick pulse time or pick duration has elapsed. The pick duration may be measured using a clock, a counter or other device known in the art for measuring time. In some embodiments the duration could be measured in terms of voltage.

If the pick pulse is continuing, then the process returns to step S14. When the pick pulse is over the process in step 26 checks for an indication that the solenoid plunger 22 moved properly. In step S26 of the illustrated embodiment, the process checks for the flag set in step S20. If the flag was set, the process ends at step S28.

When the flag is not set, then the lock may provide an aural, visual, or tactile indication to the user that the solenoid plunger 22 did not move. One example of a visual indication is flashing a light such as an LED. After receiving the indication, for example seeing the flashing LED, the user could remove the bolt pressure, if inadvertently applied, so the plunger 22 could move and lock 10 opened. Thus, the indication of the failure of the solenoid plunger 22 to move during the pick pulse would guide a user to release bolt pressure.

In the embodiment shown in FIG. 5, step S30 provides an optional process for sending multiple pick pulses to the lock 10 if the flag was not set. If the predetermined number of pick pulses have not been sent to solenoid 18 then the process could return to step S12. When the predetermined number of pick pulses have been sent then the process may end at step S28.

If optional step S30 is used this step may also provide the aural, visual, or tactile indication discussed above. Thus, if the user released the bolt pressure before the predetermined number of pick pulses were used and the solenoid plunger 22 properly moved, then the lock 10 may be opened without the user reentering a valid combination.

FIG. 10 provides one example of a solenoid motion detector 100 used to detect/measure the voltage provided from a voltage source 110 to solenoid 18. Voltage source 110 may be any voltage source. For example the voltage source may be a battery, a capacitor, or line. Other embodiments my use a current source in place of voltage source 110. This current source may be an inductor or line current.

Typically, the voltage source is connected to solenoid 18 through a switch 140 controlled by a microcontroller 130. In other embodiments a microprocessor, ASIC, or other control device may control the position of switch 140.

In the preferred embodiment, microcontroller 130 includes an A/D converter 132. The A/D converter 132 may receive the solenoid supply voltage directly or through a voltage divider 120. The voltage divider 120 is used to reduce the voltage to a voltage within the range of the A/D converter 132.

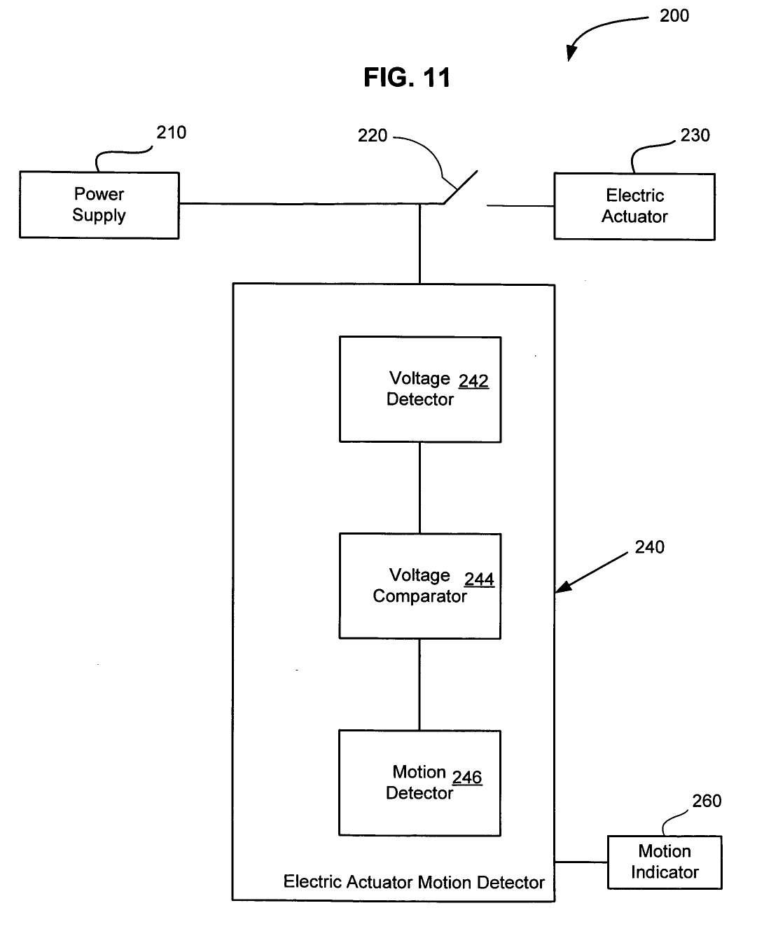

FIG. 11 illustrates an example of an electric actuator motion detector 240 used to detect the motion of an electric actuator 230. The electric actuator motion detector 240 detects/measures the voltage provided from a voltage source 210 to an electric actuator 230 via a switch 220. Voltage source 210 may be any voltage source. For example, the voltage source may be a battery, capacitor, or line voltage. Other embodiments may use a current source in place of the voltage source 210. This current source may be an inductor or line current. If line voltage and/or current is used, then the power supply circuit must permit a decrease followed by an increase in the measured voltage when the actuator moves.

Typically, the switch 220 is controlled by a microcontroller. In other embodiments, a microprocessor, ASIC, or other control device may control the position of switch 220. The electric actuator motion detector 240 typically detects the voltage supplied to electric actuator 230. The electric actuator motion detector may include a voltage detector 242 that measures/detects the voltage applied to electric actuator 230 and outputs a signal that indicates either the actual voltage detected (for example, 3.5 volts) or a number representative of the voltage detected (for example, the number 5 or representation thereof could be equal to 3 volts).

A voltage comparator 244 receives the output of voltage detector 242 and compares this voltage with either a predetermined value or a previously obtained voltage. In the preferred embodiment, the current voltage would be compared to the last obtained voltage (i.e., the voltage obtained in the last clock cycle or last measurement cycle). Other embodiments could use other previously obtained voltages or a predetermined voltage. The voltage comparator 244 outputs a signal indicating that the current voltage is larger than the voltage to which it was compared. In some embodiments, the voltage comparator may also output a signal indicating that the current voltage was smaller than, or equal to, the comparison voltage.

Motion detector 246 receives the signal output by the voltage comparator 244, and based on this output, determines whether or not the electric actuator 230 moved. In some embodiments, as discussed in the above flowcharts, the motion detector may take a single output of voltage comparator 244, indicating that the current voltage is higher than the compared voltage, as an indication that the electric actuator 230 moved. In other embodiments, the motion detector 246 may require a predetermined number of voltage comparisons, where the current voltage is higher than the compared voltage, prior to determining that the electric actuator 230 moved. In other embodiments, the predetermined number of voltage comparisons, indicating that the current voltage is higher than the compared voltage, must be consecutive.

In some embodiments, the electric actuator motion detector 240 may output a signal to a motion indicator 260. This indicator may be an audio, visual or tactile indicator. One example of an audio indicator would be a beep or other noise that the user could hear. An example of a visual indicator would be a light or LED indicator that would light. A tactile indicator could be a vibrator. Other indications or a combination of indications may be possible. The motion indicator 260 may indicate that the electric actuator properly moved or that the electric actuator failed to move.

The voltage detector 242 may be an analog-to-digital converter 132 shown in FIG. 10. Similarly, the voltage comparator 244 and motion detector 246 may be implemented as programming in a microcontroller or microprocessor 130.

The process and circuit described above is only one way to implement this invention. The same principal can be used to add other features to electronic locks. For example, when a one time combination is used in the electronic lock it would be beneficial to know that the opening operation is successfully completed before disabling that combination. The process and principles described above may also be used to detect the motion or lack of motion if electric actuators in other applications, for example robotics, electric valves, etc.

1. A method for detecting motion of an electric actuator, the method comprising:
measuring first and second supply voltages of the electric actuator, where the second measured supply voltage is measured after the first measured supply voltage;
comparing a first measured supply voltage to a second measured supply voltage; and
determining electric actuator motion when the second measured supply voltage is larger than the first measured supply voltage.

2. The method of claim 1, further comprising:
repeating the measuring, comparing and determining steps.

3. The method of claim 2, wherein the repeating step is performed a predetermined number of times.

4. The method of claim 2, wherein measuring, comparing, determining and repeating steps are performed for a predetermined time period.

5. The method of claim 2, wherein the determining step determines electric actuator motion after the second measured supply voltage is larger than the first measured supply voltage a predetermined number of times.

6. The method of claim 1, further comprising:
repeating the measuring and comparing steps, and wherein the determining step determines actuator motion when the second measured supply voltage is larger than the first measured supply voltage a predetermined number of times.

7. The method of claim 6, wherein the predetermined number of times are consecutive repetitions of the measuring and comparing steps.

8. The method of claim 1, further comprising:
after determining that the electric actuator moved, indicating that the electric actuator moved.

9. A method for detecting motion of an electric actuator, the method comprising:
measuring a plurality of supply voltages of the electric actuator;
comparing a recently measured supply voltage to a previously measured supply voltage; and
detecting motion of the electric actuator when said recently measured supply voltage is larger than said previously measured supply voltage.

10. The method of claim 9, wherein the recently measured supply voltage is a last or most recent supply voltage measured.

11. The method of claim 9, wherein the previously measured supply voltage and the recently measured supply voltage are consecutively measured voltages.

12. The method of claim 9, wherein the plurality of supply voltages are measured periodically.

13. The method of claim 9, wherein the plurality of supply voltages are measured for a predetermined period of time.

14. The method of claim 9, wherein a predetermined number of supply voltages is measured.

15. The method of claim 9, further comprising:
after detecting motion of the electric actuator, indicating that the electric actuator has moved.

16. A method of detecting motion of an electric actuator, the method comprising:
measuring a supply voltage;
comparing the supply voltage to a predetermined value; and
detecting motion of the electric actuator when the supply voltage is larger than the predetermined value.

17. The method of claim 16, further comprising:
after detecting motion of the electric actuator, indicating that the electric actuator has moved.

18. The method of claim 16, further comprising:
repeating the measuring, comparing and detecting steps.

19. The method of claim 18, wherein the repeating step is performed a predetermined number of times.

20. The method of claim 18, wherein measuring, comparing, and repeating steps are performed for a predetermined time period.

21. The method of claim 18, wherein the detecting step detects electric actuator motion after the second measured supply voltage is larger than the first measured supply voltage a predetermined number of times.

22. The method of claim 16, further comprising:
repeating the measuring and comparing steps, and wherein the detecting step detects actuator motion when the second measured supply voltage is larger than the first measured supply voltage a predetermined number of times.

23. The method of claim 22, wherein the predetermined number of times are consecutive repetitions of the measuring and comparing steps.

24. An electric actuator motion detector comprising:
a voltage detector, the voltage detector measures a supply voltage of an electric actuator;
a voltage comparator electrically connected to the voltage detector, the comparator, receiving the signal output from the voltage detector, compares the supply voltage with a previous voltage and outputs a first signal when the supply voltage is larger than the previous voltage; and
a motion detector connected to the voltage comparator, the motion detector detects motion when the first signal is received from the voltage comparator a predetermined number of times.

25. The detector of claim 24, wherein the predetermined number is 2 or larger.

26. The detector of claim 24, wherein the predetermined number is selected from the group consisting of positive integers.

27. The detector of claim 26, wherein the predetermined number is less than 10.

28. The detector of claim 24, further comprising an indicator connected to the motion detector.

29. The detector of claim 28, wherein the indicator indicates that the electric actuator moved.

30. The detector of claim 28, wherein the indicator indicates that the electric actuator failed to move.

31. The detector of claim 28, wherein the indicator provides a first indication indicating that the electric actuator moved and a second indication indicating that the electric actuator failed to move.

32. The detector of claim 24, wherein the voltage detector is an analog-to-digital converter and wherein the voltage comparator and the motion detector are formed in a programmable microprocessor or microcontroller.

33. The detector of claim 24, wherein the detector is formed in an ASIC.

34. An electric actuator motion detector comprising:
a voltage detector, the voltage detector measures a supply voltage of an electric actuator;
a voltage comparator electrically connected to the voltage detector, the comparator, receiving the signal output from the voltage detector, compares the supply voltage with a predetermined voltage and outputs a first signal when the supply voltage is larger than the predetermined voltage; and
a motion detector connected to the voltage comparator, the motion detector detects motion when the first signal is received from the voltage comparator a predetermined number of times.

35. The detector of claim 34, wherein the predetermined number is 2 or larger.

36. The detector of claim 34, wherein the predetermined number is selected from the group consisting of positive integers.

37. The detector of claim 36, wherein the predetermined number is less than 10.

38. The detector of claim 34, further comprising an indicator connected to the motion detector.

39. The detector of claim 38, wherein the indicator indicates that the electric actuator moved.

40. The detector of claim 38, wherein the indicator indicates that the electric actuator failed to move.

41. The detector of claim 38, wherein the indicator provides a first indication indicating that the electric actuator moved and a second indication indicating that the electric actuator failed to move.

42. The detector of claim 34, wherein the voltage detector is an analog-to-digital converter and wherein the voltage comparator and the motion detector are formed in a programmable microprocessor or microcontroller.

43. The detector of claim 34, wherein the detector is formed in an ASIC.
